(19) United States
(12) Patent Application Publication
(10) Pub. No.: US 2023/0328993 A1
(43) Pub. Date: Oct. 12, 2023

(54) MEMORY DEVICE AND METHOD OF MANUFACTURING THE SAME

(71) Applicant: SK hynix Inc., Icheon-si Gyeonggi-do (KR)

(72) Inventors: Chul Young KIM, Icheon-si Gyeonggi-do (KR); Jin Ho BIN, Icheon-si Gyeonggi-do (KR); Sun Woo KIM, Icheon-si Gyeonggi-do (KR); Ah Reum BAHK, Icheon-si Gyeonggi-do (KR); Ji Yeon BAEK, Icheon-si Gyeonggi-do (KR)

(73) Assignee: SK hynix Inc., Icheon-si Gyeonggi-do (KR)

(21) Appl. No.: 17/950,740

(22) Filed: Sep. 22, 2022

(30) Foreign Application Priority Data
Mar. 24, 2022 (KR) 10-2022-0036954

(51) Int. Cl. H01L 27/1157; H01L 27/11582

(52) U.S. Cl. CPC H01L 27/1157; H01L 27/11582

(57) ABSTRACT

The present technology includes a memory device and a method of manufacturing the same. The memory device includes a source line including a plurality of source layers and a buffer layer, the buffer layer being formed between the plurality of source layers, a stack structure formed on the source line, a cell plug contacting the source line by passing through the stack structure, a slit separating the stack structure, and a source contact formed in the slit and contacting the source line.

### CROSS-REFERENCE TO RELATED APPLICATION

The present application claims priority under 35 U.S.C. § 119(a) to Korean patent application number 10-2022-0036954, filed on Mar. 24, 2022, in the Korean Intellectual Property Office, the entire disclosure of which is incorporated herein by reference.

### BACKGROUND

### 1. Technical Field

The present disclosure relates to a memory device and a method of manufacturing the same, and more particularly, to a memory device having a three-dimensional structure and a method of manufacturing the same.

### 2. Related Art

A memory device may be divided into a volatile memory device in which stored data is destroyed when power supply is cut off, and a non-volatile memory device in which stored data is maintained even though power supply is cut off.

The non-volatile memory device may include a NAND flash memory, a NOR flash memory, a resistive random access memory (ReRAM), a phase-change random access memory (PRAM), a magneto resistive random access memory (MRAM), a ferroelectric random access memory (FRAM), a spin transfer torque random access memory (STT-RAM), and the like.

Among these, a memory block included in the NAND flash memory may be formed between a bit line and a source line. The memory block may include a plurality of strings including memory cells. For example, the strings may include first select transistors, memory cells, and second select transistors connected between the bit line and the source line. Gates of the first select transistors may be connected to first select lines, gates of the memory cells may be connected to word lines, and gates of the second select transistors may be connected to second select lines.

In order to perform a program, read, or erase operation of the memory device, various operation voltages may be transmitted through conductive lines connected to the memory block. Therefore, a resistance of the conductive lines is required to be low.

However, as an integration degree of the memory device increases, a seam may be generated between the conductive lines in a step of forming the conductive lines, and such a seam may increase the resistance of the conductive lines.

### SUMMARY

According to an embodiment of the present disclosure, a memory device includes a memory device and a method of manufacturing the same. The memory device includes a source line including a plurality of source layers and a buffer layer, the buffer layer being formed between the plurality of source layers, a stack structure formed on the source line, a cell plug contacting the source line by passing through the stack structure, a slit separating the stack structure, and a source contact formed in the slit and contacting the source line.

According to an embodiment of the present disclosure, a method of manufacturing a semiconductor memory device includes stacking a first sacrificial layer and a second source layer on a first source layer, forming a landing hole that exposes a portion of the first source layer by etching the second source layer, the first sacrificial layer, and a portion of the first source layer, forming a cell plug inside the landing hole, forming a slit that exposes a portion of the first sacrificial layer by etching the second source layer and a portion of the first sacrificial layer, forming a recess between the first and second source layers by removing the first sacrificial layer that is exposed through the slit, forming a buffer layer along a surface of the first and second source layers exposed through the recess, forming a third source layer in the recess in which the buffer is formed to form a source line including the first to third source layers and the buffer layer, and forming a source contact in the slit.

### BRIEF DESCRIPTION OF THE DRAWINGS

FIG. 1 is a diagram illustrating a memory device according to an embodiment of the present disclosure.

FIG. 2 is a diagram illustrating a memory cell array.

FIG. 3 is a circuit diagram illustrating a memory block according to an embodiment of the present disclosure.

FIG. 4 is a plan view illustrating a structure of a memory device according to an embodiment of the present disclosure.

FIG. 5 is a cross-sectional view illustrating a structure of a memory device according to an embodiment of the present disclosure.

FIGS. 6A and 6B are diagrams illustrating a function of a buffer layer according to the present embodiment.

FIGS. 7A to 7Q are diagrams illustrating a method of manufacturing a memory device according to an embodiment of the present disclosure.

FIG. 8 is a diagram illustrating a memory card system to which a memory device of the present disclosure is applied.

FIG. 9 is a diagram illustrating a solid state drive (SSD) system to which a memory device of the present disclosure is applied.

### DETAILED DESCRIPTION

Specific structural or functional descriptions of embodiments according to the concept which are disclosed in the present specification or application are illustrated only to describe the embodiments according to the concept of the present disclosure. The embodiments according to the concept of the present disclosure may be carried out in various forms and should not be construed as being limited to the embodiments described in the present specification or application.

An embodiment of the present disclosure provides a memory device and a method of manufacturing the same for suppressing formation of a seam in a source line.

The present technology may prevent a resistance increase of a source line by suppressing formation of a seam in the source line.

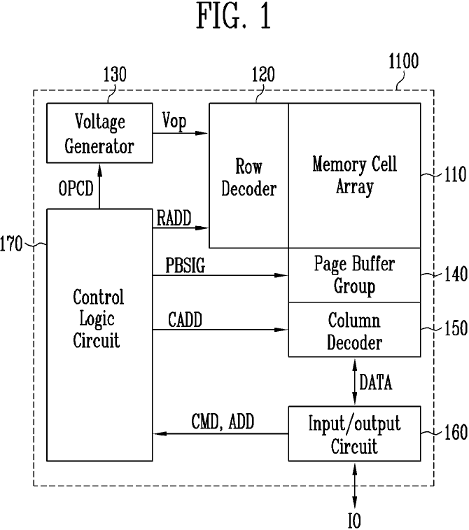

FIG. 1 is a diagram illustrating a memory device according to an embodiment of the present disclosure.

Referring to FIG. 1, the memory device 1100 may include a memory cell array 110 in which data is stored, and peripheral circuits 120 to 170 capable of performing a program, read, or erase operation.

The memory cell array 110 may include a plurality of memory blocks in which data is stored. Each of the memory blocks may include memory cells, and the memory cells may be implemented in a three-dimensional structure in which the memory cells are stacked on a substrate in a vertical direction.

The peripheral circuits 120 to 170 may include a row decoder 120, a voltage generator 130, a page buffer group 140, a column decoder 150, and an input/output circuit 160, and a control logic circuit 170.

The row decoder 120 may select one memory block from among the memory blocks that are included in the memory cell array 110 according to a row address RADD and may transmit operation voltages Vop to the selected memory block.

In response to an operation code OPCD, the voltage generator 130 may generate and output the operation voltages Vop that are required for various operations. For example, the voltage generator 130 may generate a program voltage, a read voltage, an erase voltage, a pass voltage, a turn-on voltage, a ground voltage, and the like in response to the operation code OPCD and may selectively output the generated voltages.

The page buffer group 140 may be connected to the memory cell array 110 through bit lines. For example, the page buffer group 140 may include page buffers that are connected to each of the bit lines. The page buffers may operate simultaneously in response to page buffer control signals PBSIG and may temporarily store data during a program, read, or verify operation. During the read or verify operation, the page buffers may sense a current of the bit lines, which varies according to a threshold voltage of the memory cells.

The column decoder 150 may transmit data DATA between the input/output circuit 160 and the page buffer group 140 according to a column address CADD.

The input/output circuit 160 may be connected to an external device through input/output lines IO. For example, the external device may be a controller capable of transmitting a command CMD, an address ADD, or the data DATA to the memory device 1100. The input/output circuit 160 may input/output the command CMD, the address ADD, and the data DATA through the input/output lines IO. For example, the input/output circuit 160 may transmit the command CMD and the address ADD that are received from the external device through the input/output lines IO to the control logic circuit 170 and may transmit the data DATA that is received from the external device through the input/output lines IO to the column decoder 150. The input/output circuit 160 may output the data DATA that is received from the column decoder 150 to the external device through the input/output lines IO.

The control logic circuit 170 may output the operation code OPCD, the row address RADD, the page buffer control signals PBSIG, and the column address CADD in response to the command CMD and the address ADD. For example, the control logic circuit 170 may include software performing an algorithm in response to the command CMD and hardware configured to output the address ADD and various control signals.

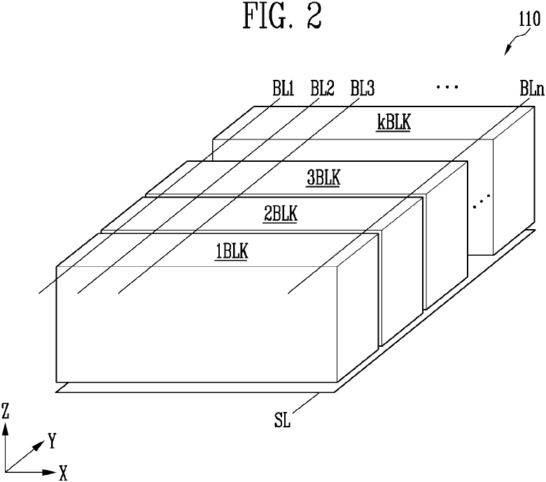

FIG. 2 is a diagram illustrating the memory cell array.

Referring to FIG. 2, the memory cell array 110 may include first to k-th (k is a positive integer) memory blocks 1BLK to kBLK. Each of the first to k-th memory blocks 1BLK to kBLK may include a plurality of memory cells that are stacked from a substrate in a vertical direction. The first to k-th memory blocks 1BLK to kBLK may be disposed between a source line SL and first to n-th bit lines BL1 to BLn. For example, when the first to n-th bit lines BL1 to BLn are disposed to be spaced apart from each other in a first direction (X direction) and are formed to extend in a second direction (Y direction) that is perpendicular to the first direction (X direction), the first to k-th memory blocks 1BLK to kBLK may be disposed to be spaced apart from each other in the second direction (Y direction). Therefore, the memory cells that are included in the first to k-th memory blocks 1BLK to kBLK may be stacked along a third direction Z, perpendicular to the first and second directions (X and Y directions).

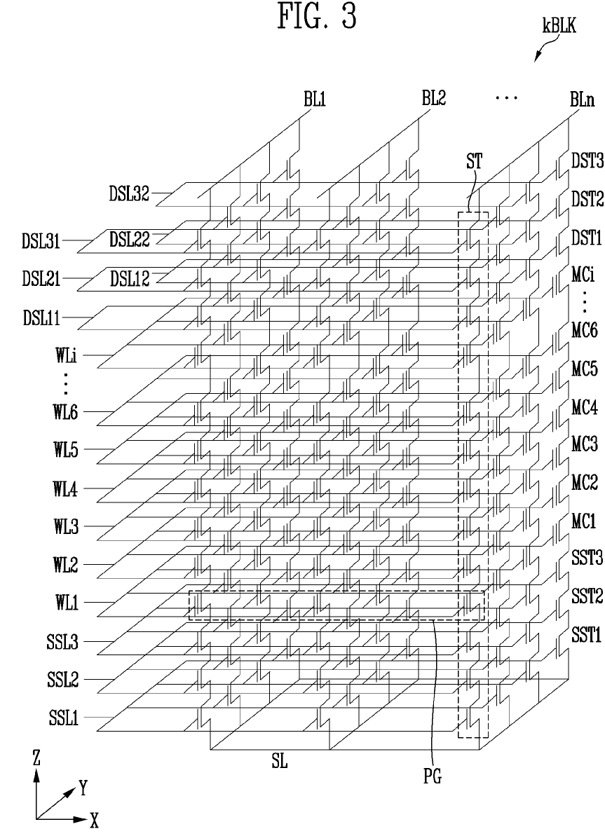

FIG. 3 is a circuit diagram illustrating a memory block according to an embodiment of the present disclosure.

Referring to FIG. 3, since the first to k-th memory blocks 1BLK to kBLK of FIG. 2 are configured identically to each other, the k-th memory block kBLK is shown as an example.

The k-th memory block kBLK may include strings ST that are connected between the first to n-th bit lines BL1 to BLn and the source line SL. Since the first to n-th bit lines BL1 to BLn extend along the second direction (Y direction) and are arranged to be spaced apart from each other in the first direction (X direction), the strings ST may also be arranged to be spaced apart from each other in the first and second directions (X and Y directions). For example, the strings ST may be connected between the first bit line BL1 and the source line SL, and the strings ST may be arranged between the second bit line BL2 and the source line SL. In such a method, the strings ST may be arranged between the n-th bit line BLn and the source line SL. The strings ST may extend in the third direction (Z direction).

When any one string ST, among the strings ST that are connected to the n-th bit line BLn, is described as an example, the string ST may include first to third source select transistors SST1 to SST3, first to i-th memory cells MC1 to MCi, and first to third drain select transistors DST1 to DST3. Since FIG. 3 is a diagram for understanding a structure of the memory block, the number of source select transistors, memory cells, and drain select transistors that are included in the strings ST may be changed according to the memory device.

Gates of the first to third source select transistors SST1 to SST3 that are included in different strings may be connected to the first to third source select lines SSL1 to SSL3, respectively. Gates of the first to i-th memory cells MC1 to MCi may be connected to first to i-th word lines WL1 to WLi, respectively. Gates of the first to third drain select transistors DST1 to DST3 may be connected to eleventh, twelfth, twenty-first, twenty-second, thirty-first, and thirty-second drain select lines DSL11, DSL12, DSL21, DSL22, DSL31, and DSL32, respectively.

For example, the first source select line SSL1 may be commonly connected to the first source select transistors SST1 that are arranged at the same distance from the substrate. In other words, the first source select transistors SST1 that are formed on the same layer may be commonly connected to the first source select line SSL1. In such a method, the second source select transistors SST2 that are formed on a different layer from that of the first source select transistors SST1 may be commonly connected to the second source select line SSL2, and the third source select transistors SST3 that are formed on a different layer from that of the second source select transistors SST2 may be commonly connected to the third source select line SSL3. The first to third source select lines SSL1 to SSL3 may be formed on different layers, respectively.

In the method described above, the i-th memory cells MCi that are formed on the same layer may be commonly connected to the i-th word line WLi, and the first to i-th word lines WL1 to WLi may be formed on different layers, respectively. A group of memory cells that are included in different strings ST and connected to the same word line becomes a page PG.

The first to third drain select transistors DST1 to DST3 that are included in different strings ST may be connected to drain select lines that are separated from each other. Specifically, each of the first to third drain select transistors DST1 to DST3 that are arranged along the first direction (X direction) may be connected to the same drain select line, and the first to third drain select transistors DST1 to DST3 that are arranged along the second direction (Y direction) may be connected to drain select lines that are separated from each other. For example, a portion of the first drain select transistors DST1 may be connected to the eleventh drain select line DSL11, and a remainder may be connected to the twelfth drain select line DSL12. The twelfth drain select line DSL12 is a line that is separated from the eleventh drain select line DSL11. Therefore, a voltage that is applied to the eleventh drain select line DSL11 may be different from a voltage that is applied to the twelfth drain select line DSL12. In such a method, a portion of the second drain select transistors DST2 may be connected to the twenty-first drain select line DSL21, and a remainder may be connected to the twenty-second drain select line DSL22. A portion of the third drain select transistors DST3 may be connected to the thirty-first drain select line DSL31, and a remainder may be connected to the thirty-second drain select line DSL32.

Although not shown in FIG. 3, dummy lines may be disposed between the drain select line and the word line, and dummy lines may also be disposed between the source select line and the word line.

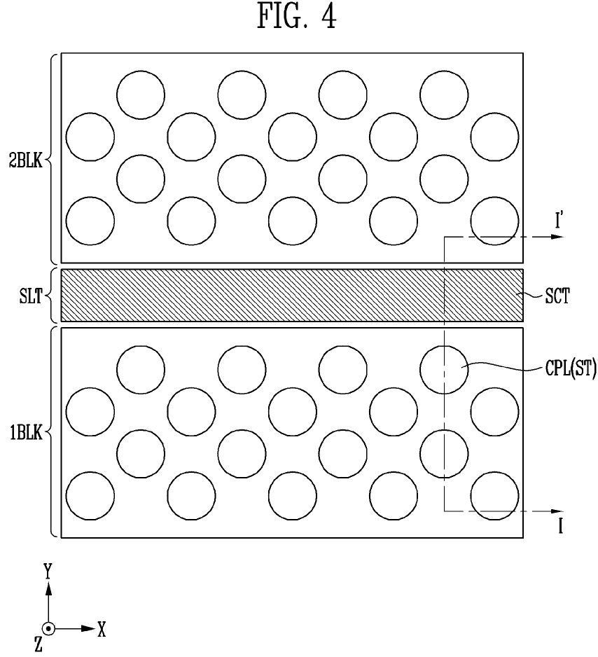

FIG. 4 is a plan view illustrating a structure of a memory device according to an embodiment of the present disclosure.

Referring to FIG. 4, seen in a plan view, first and second memory blocks 1BLK and 2BLK may be formed on a plane of the first and second directions X and Y. The first and second memory blocks 1BLK and 2BLK may be divided from each other by a slit SLT. When the slit SLT extends in the first direction X, the first and second memory blocks 1BLK and 2BLK may be disposed to be divided from each other in the second direction Y. Since FIG. 4 shows an embodiment of an area in which the first and second memory blocks 1BLK and 2BLK, among the first to k-th memory blocks 1BLK to kBLK that are included in the memory cell array 110 as shown in FIG. 2, are formed, the remaining second to k-th memory blocks 2BLK to kBLK may also be divided by the slit SLT. The area, among areas in which the first to k-th memory blocks 1BLK to kBLK are formed, in which the first and second memory blocks 1BLK and 2BLK are formed, is described as an example as follows.

A plurality of cell plugs CPL may be included in the first and second memory blocks 1BLK and 2BLK. Each of the cell plugs CPL may correspond to the string ST that is described with reference to FIG. 3. For example, the cell plugs CPL may be arranged to be spaced apart from each other in the first or second direction X or Y and may extend along the third direction Z that is perpendicular to the substrate. Since gate lines of memory cells, among the plurality of memory cells that are included in the same memory block, formed on the same plane, are connected to each other, the gate lines of the memory blocks that are formed on the same plane and different from each other may be separated from each other by the slit SLT.

The slit SLT may be filled with an insulating material, but to reduce the size of the memory device, a source contact SCT may be formed in the slit SLT. The source contact SCT may transmit a source voltage that is supplied through a line that is formed on the first and second memory blocks 1BLK and 2BLK to a source line that is formed under the first and second memory blocks 1BLK and 2BLK. Since the source line is commonly connected to the plurality of memory blocks, an electrical characteristic change of the source line may affect the plurality of memory blocks. In the present embodiment, during an etching process for forming a landing hole, in order to prevent a physical defect of the source line that is exposed through the landing hole and reduce the resistance of an area in which the source contact SCT and the source line contact each other, a compensation plug including an impurity of a high concentration may be formed under the cell plug. A memory device including the compensation plug and a method of manufacturing the memory device are specifically described as follows.

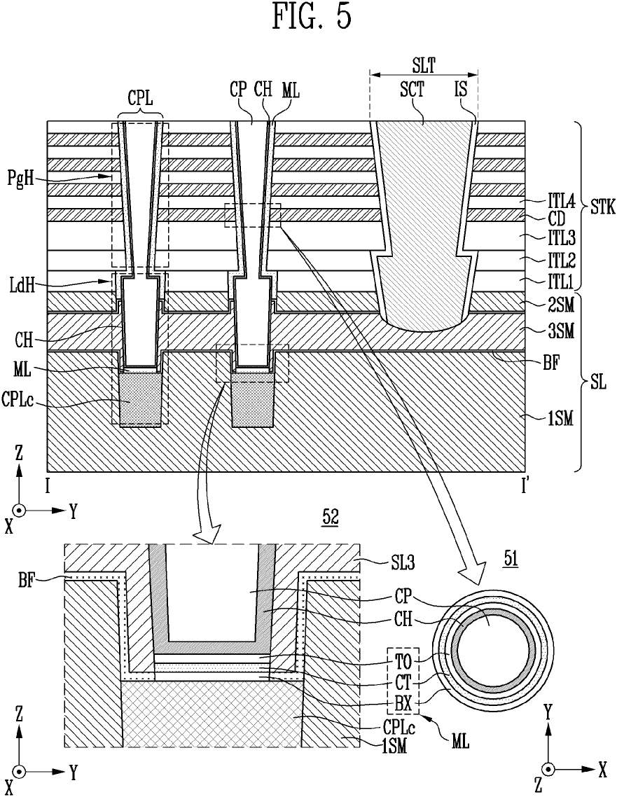

FIG. 5 is a cross-sectional view illustrating a structure of a memory device according to an embodiment of the present disclosure.

Referring to FIG. 5, the memory device may include a source line SL, a stack structure STK, cell plugs CPL, compensation plugs CPLc, and a source contact SCT that are formed on a lower structure (not shown). The lower structure may be a substrate or a peripheral circuit structure. Since the compensation plugs CPLc are structures for reducing the resistance between the source line SL and the cell plugs CPL, the compensation plugs CPLc may be omitted according to the memory device. In a memory device without the compensation plugs CPLc, the cell plugs CPL, instead of the compensation plugs CPLc, may further extend downward into the source line SL.

The source line SL may include first to third source layers 1SM to 3SM and a buffer layer BF. For example, the third source layer 3SM may be formed on the first source layer 1SM, the second source layer 2SM may be formed on the third source layer 3SM, and the buffer layer BF may be formed between the first to third source layers 1SM to 3SM. The first, third, and second source layers 1SM, 3SM, and 2SM may be formed of a conductive material. For example, the first, third, and second source layers 1SM, 3SM, and 2SM may be formed of a conductive material, such as polysilicon, tungsten, or nickel, or may be formed of various other types of conductive materials or a combination of conductive materials. The buffer layer BF may be formed of an insulating material capable of reducing the growth speed of the third source layer 3SM that is formed between the first and second source layers 1SM and 2SM. The buffer layer BF may reduce the speed at which a grain size grows compared to a case in which the third source layer 3SM is formed from the first or second source layer 1SM or 2SM. The buffer layer BF may be formed of at least one of an oxide layer, a nitride layer, SiON, and SiCN. The buffer layer BF may be formed through various methods, such as a chemical vapor deposition method, a wet oxidation method, or a natural oxidation method, and may be formed as an amorphous layer. When the buffer layer BF is formed through a chemical vapor deposition method, the buffer layer BF may be formed as a layer that is deposited along a surface of the first and second source layers 1SM and 2SM. When the buffer layer BF is formed through a wet oxidation method or a natural oxidation method, the buffer layer BF may be formed as a layer in which a portion of the surface of the first and second source layers 1SM and 2SM is oxidized. Since FIG. 5 is a diagram to help with understanding the present embodiment, the number of first to third source layers 1SM to 3SM and the buffer layer BF, shown in FIG. 5, is merely an embodiment and may be changed according to the memory device. For example, when the number of source layers is N (N is an integer greater than or equal to 2), the number of buffer layers BF may be N-1.

The stack structure STK may include first to third interlayer insulating layers ITL1 to ITL3 that are stacked on the source line SL, and conductive layers CD and fourth interlayer insulating layers ITL4 that are stacked alternately on the source line SL. The first to fourth interlayer insulating layers ITL1 to ITL4 may be formed of an oxide layer or a silicon oxide layer. The conductive layers CD may be formed of a conductive material that may be used as a gate line. For example, the conductive layers CD may be formed of a metal material, such as tungsten (W), molybdenum (Mo), cobalt (Co), or nickel (Ni), or a semiconductor material such as silicon (Si) or polysilicon (Poly-Si) but are not limited thereto.

The cell plug CPL may pass through the stack structure STK and protrude into a portion of the source line SL. For example, the cell plug CPL may pass through the stack structure STK along the third direction Z, and a lower portion of the cell plug CPL may protrude into the source line SL. The cell plug CPL may be formed in a portion of a landing hole LdH that is formed in the source line SL and inside a plug hole PgH that is formed in the stack structure STK. A portion of an upper area of the landing hole LdH may overlap with a portion of a lower area of the stack structure STK. The cell plug CPL may include a memory layer ML, a channel layer CH, and a core pillar CP that are formed in a portion of the landing hole LdH and inside the plug hole PgH. For example, the memory layer ML may be formed in a cylindrical shape along a partial inner wall of the landing hole LdH and an inner wall of the plug hole PgH, and the channel layer CH may be formed in a cylindrical shape along an inner wall of the memory layer ML. The core pillar CP may be formed in a cylindrical shape along an inner wall of the channel layer CH.

A portion of the memory layer ML that is formed on the same layer as the conductive layers CD may become a memory cell. The memory cell is described with reference to an enlarged plan view 51. The memory cell may include a core pillar CP having a cylindrical shape and may include a channel layer CH that surrounds a side surface of the core pillar CP, a tunnel insulating layer TO that surround a side surface of the channel layer CH, a charge trap layer CT that surrounds a side surface of the tunnel insulating layer TO, and a blocking layer BX that surrounds a side surface of the charge trap layer CT. The tunnel insulating layer TO, the charge trap layer CT, and the blocking layer BX that surround the channel layer CH may be included in the memory layer ML.

The channel layer CH that is included in the cell plug CPL may extend in the third direction Z in the plug hole PgH and the landing hole LdH. However, a portion of the memory layer ML may be removed in the landing hole LdH. Specifically, the portion of the memory layer ML may be removed in an area in which the source line SL and the cell plug CPL overlap. In an area in which a portion of the memory layer ML is removed, the channel layer CH may contact the source line SL.

The compensation plug CPLc may be formed under the cell plug CPL in the landing hole LdH. The compensation plug CPLc may be formed in the first source layer 1SM that is included in the source line SL, but the height of the uppermost end of the compensation plug CPLc may be set at a lower position than the height of the uppermost end of the first source layer 1SM.

Referring to an enlarged view 52 of a partial area in which the buffer layer BF is formed, the buffer layer BF may be formed along a surface of the first source layer 1SM and a portion of a surface of the compensation plug CPLc. The compensation plug CPLc may be a layer to reduce a resistance between the cell plug CPL and the source line SL and may be formed of a material including an impurity of a higher concentration than that of an impurity that is included in the first or second source layer 1SM or 2SM. The impurity that is included in the compensation plug CPLc may be the same ion as the impurity that is included in the first to third source layers 1SM to 3SM or an ion capable of reducing the resistance of the source line SL. For example, the impurity that is included in the compensation plug CPLc may be a phosphorous or boron ion. In addition, a material including various ions capable of improving an electrical characteristic of the source line SL may be used as the compensation plug CPLc.

The source contact SCT may pass through the stack structure STK and may protrude into a portion of the source line SL. For example, the source contact SCT may pass through the stack structure STK along the third direction Z, and a portion of a lower portion of the source contact SCT may protrude into the source line SL. The source contact SCT may be formed in the slit SLT to separate the conductive layers CD that are included in the stack structure STK. For example, the slit SLT may be a trench that separates the conductive layers CD and the fourth interlayer insulating layers ITL4 that are included in the stack structure STK in the first direction X. The slit SLT may be formed to expose a portion of the source line SL. Since the conductive layers CD may be exposed through a side surface of the slit SLT, an insulating layer IS may be formed on a side surface of the slit SLT. Therefore, the source contact SCT that is formed of a conductive material may be formed inside the slit SLT in which the insulating layer IS is formed. The source contact SCT might not contact the conductive layers CD of the stack structure STK but may contact the source line SL. The source contact SCT may be formed of a conductive material. For example, the source contact SCT may be formed of a conductive material, such as polysilicon or tungsten.

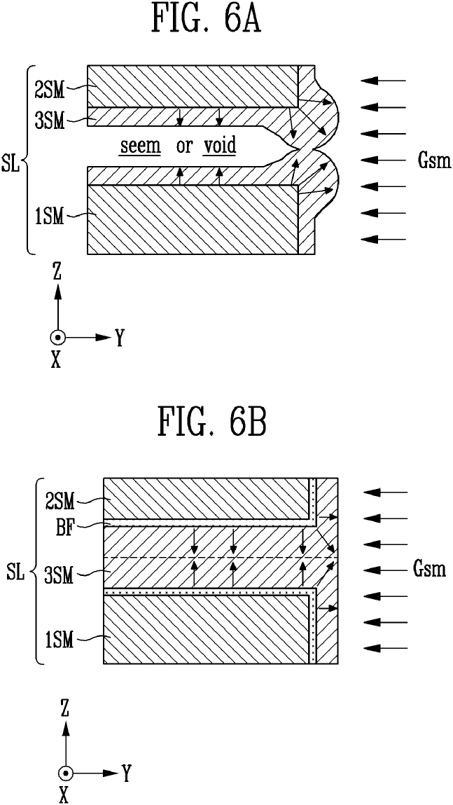

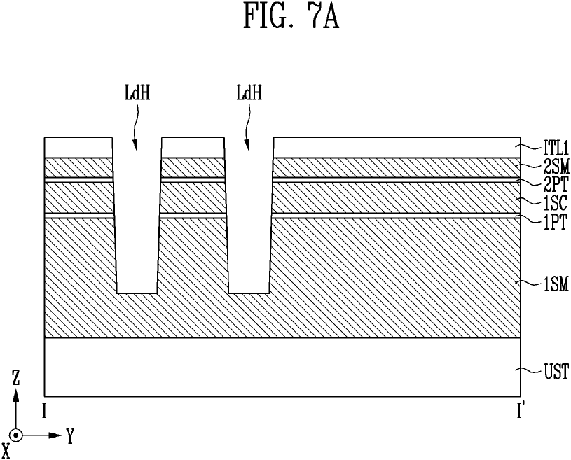

FIGS. 6A and 6B are diagrams illustrating a function of the buffer layer according to the present embodiment. FIG. 6A is a diagram illustrating a method of forming the source layer in a structure in which the buffer layer BF does not exist, and FIG. 6B is a diagram illustrating a method of forming the source layer in a structure in which the buffer layer BF exists.

Referring to FIG. 6A, when the third source layer 3SM is formed between the first and second source layers 1SM and 2SM, the third source layer 3SM may be grown from the surface of the first and second source layers 1SM and 2SM since the surface of the first and second source layers 1SM and 2SM are exposed. That is, the surface of the first and second source layers 1SM and 2SM may become a seed for the third source layer 3SM. Since the first to third source layers 1SM to 3SM are formed of conductive materials that are similar or identical to each other, a growth speed of the third source layer 3SM that is formed from the surface of the first and second source layers 1SM and 2SM may be fast. For example, the first to third source layers 1SM to 3SM may be formed of a conductive material, such as polysilicon, tungsten, or nickel and may be formed of various other conductive materials.

In particular, as seen in FIG. 6A, since the corner portions of the first and second source layers 1SM and 2SM are portions where two planes are in contact with each other, the third source layer 3SM that is formed in the two planes are in contact with each other. Therefore, the growth speed of the third source layer 3SM near the corner portion may be faster than the growth speed of the third source layer 3SM that is formed along the rest of the plane. Accordingly, before the third source layer 3SM is sufficiently filled between the first and second source layers 1SM and 2SM, the third source layers 3SM may come into contact with each other near an edge portion where the first and second source layers 1SM and 2SM face each other due to the faster growth speed near the corner portions of the first and second source layers 1SM and 2SM. When a source gas Gsm for forming the third source layer 3SM is supplied to the corner portion, the faster accumulating third source layer 2SM near the corner portion may block the source gas Gsm from moving farther into the space between the first and second source layers 1SM and 2SM. The blockage may result in the third source layer 3SM being insufficiently filled between the first and second source layers 1SM and 2SM, and thus, a seam or a void may occur. Since the first to third source layers 1SM to 3SM are used as the source line SL, when the size of the seam or the void that is formed in the source line SL increases, the resistance of the source line SL may also increase.

Referring to FIG. 6B, in order to prevent the occurrence of the seam or the void, described with reference to FIG. 6A, in the present embodiment, the buffer layer BF may be formed along the surface of the first and second source layers 1SM and 2SM. The buffer layer BF may be used as a layer for suppressing the first and second source layers 1SM and 2SM from acting as a direct seed for the third source layer 3SM in a step of forming the third source layer 3SM. In other words, the buffer layer BF may be used as a layer for reducing the growth speed of the third source layer 3SM. Since the source gas Gsm for forming the third source layer 3SM includes a conductive source gas, the buffer layer BF for reducing the growth speed of the third source layer 3SM may be formed of an insulating material. The buffer layer BF may be formed of at least one of an oxide layer, a nitride layer, SiON, and SiCN. The buffer layer BF may be formed through various methods, such as a chemical vapor deposition method, a wet oxidation method, or a natural oxidation method and may be formed of an amorphous layer. When the buffer layer BF is formed through the chemical vapor deposition method, the buffer layer BF may be formed as a layer that is deposited along the surface of the first and second source layers 1SM and 2SM. When the buffer layer BF is formed through the wet oxidation method or the natural oxidation method, the buffer layer BF may be formed as a layer in which the surface of the first and second source layers 1SM and 2SM is partially oxidized.

The buffer layer BF may be formed to have a thin thickness so that the source gas Gsm for forming the third source layer 3SM is prevented from directly contacting the first and second source layers 1SM and 2SM, resulting in a current flowing between the first to third source layers 1SM to 3SM. For example, a minimum thickness of the buffer layer BF may be a thickness of one atomic layer, and a maximum thickness may be a thickness of the memory layer ML of FIG. 5. The thickness of the buffer layer BF may be adjusted according to a type of the first to third source layers 1SM to 3SM or an electrical characteristic of the entire source line SL.

When the source gas Gsm for the third source layer 3SM is supplied to the structure in which the buffer layer BF is formed on the surface of the first and second source layers 1SM and 2SM, the third source layer 3SM may be formed while source ions that are included in the source gas combine with the buffer layer BF. At this time, since the source ions that are included in the source gas Gsm do not directly contact the first and second source layers 1SM and 2SM but directly contact the buffer layer BF, the growth speed of the third source layer 3SM may be reduced.

When the growth speed of the third source layer 3SM is reduced, the third source layer 3SM may be formed to have a uniform thickness along the entire surface including the corner of the first and second source layers 1SM and 2SM. Therefore, a phenomenon in which a seam or a void occurs between the first and second source layers 1SM and 2SM may be suppressed.

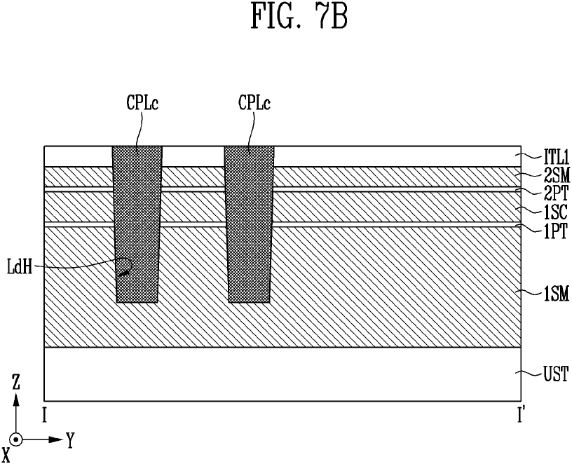

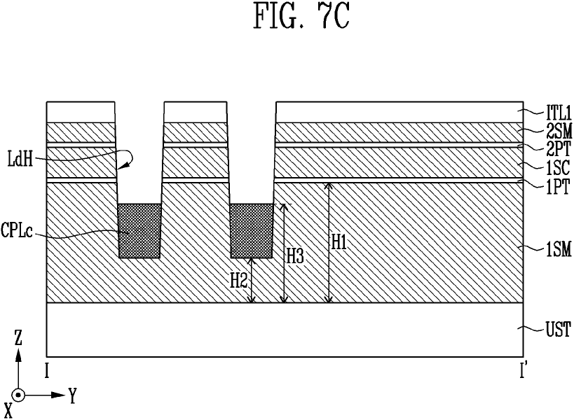

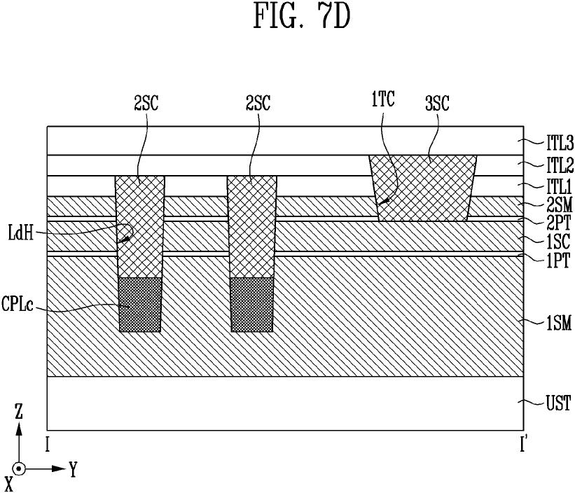

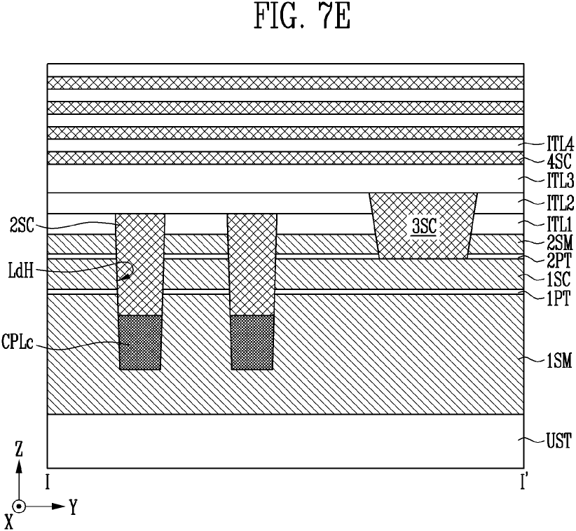

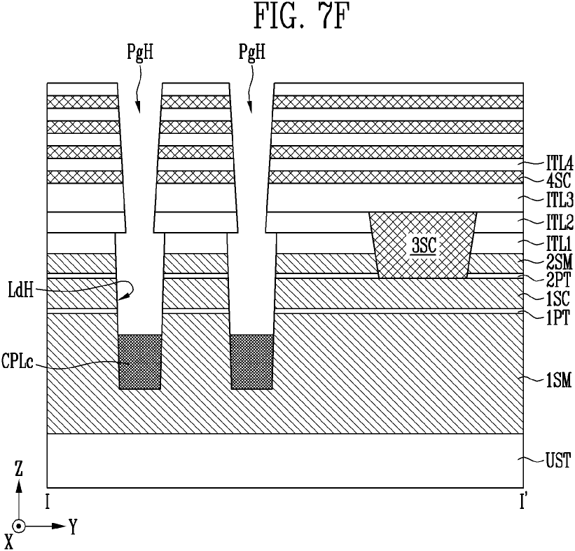

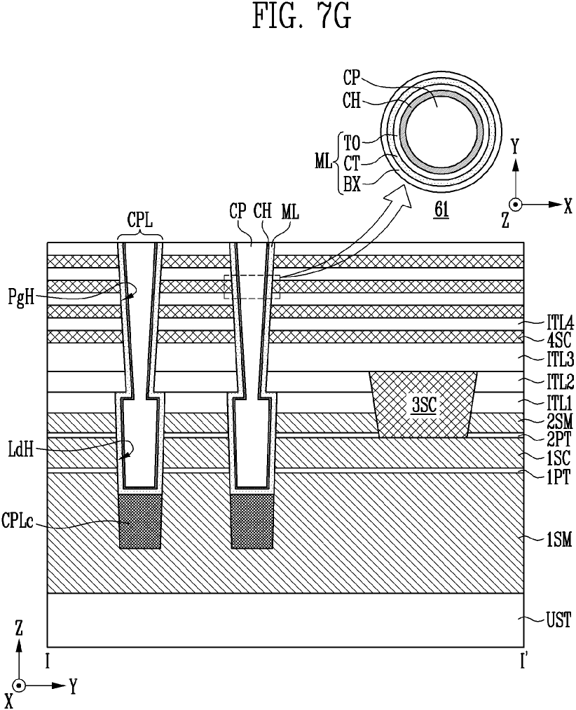

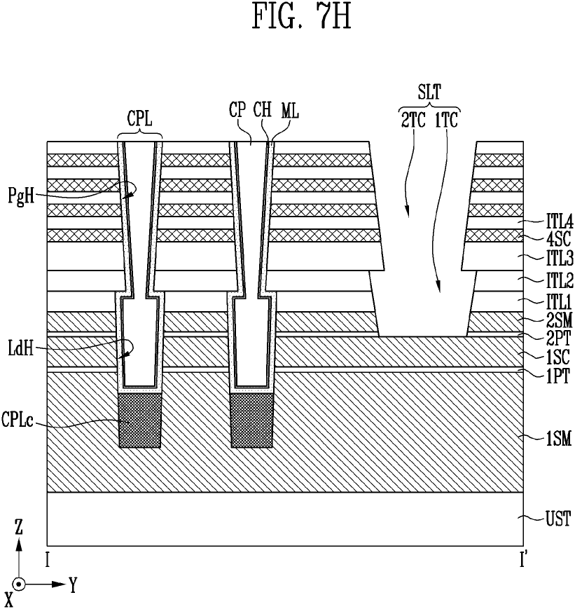

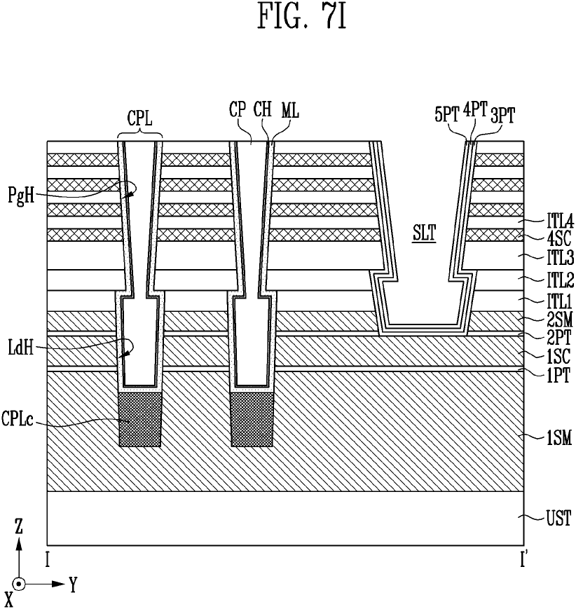

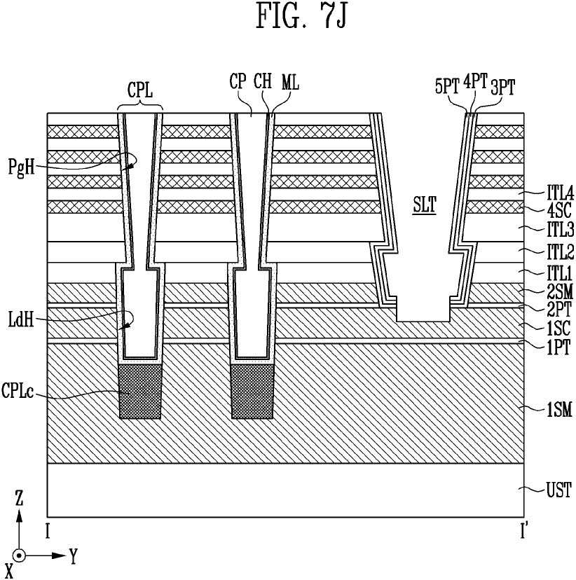

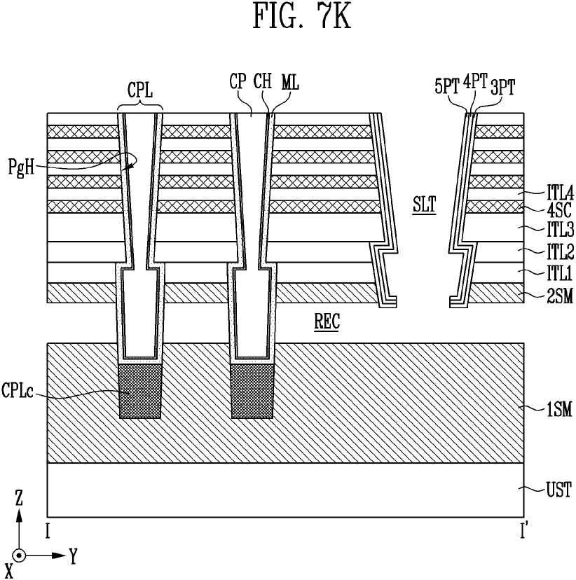

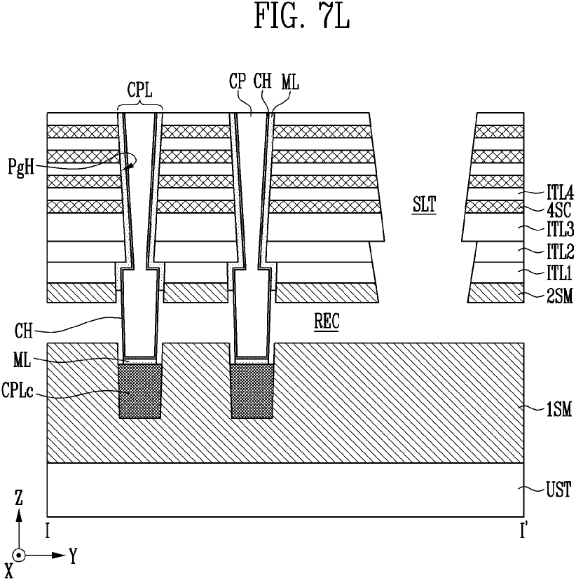

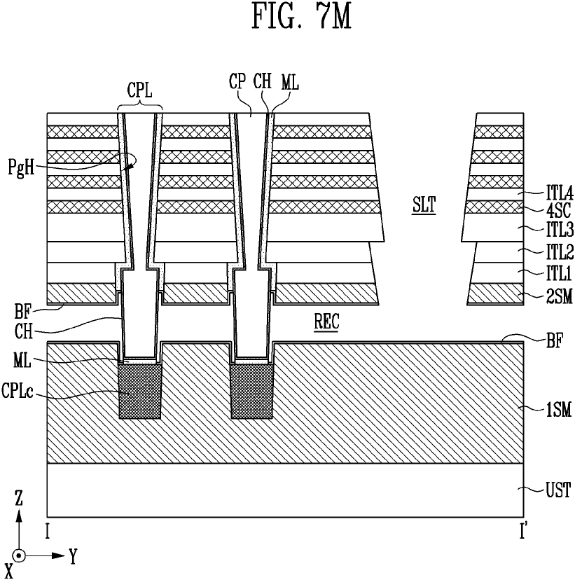

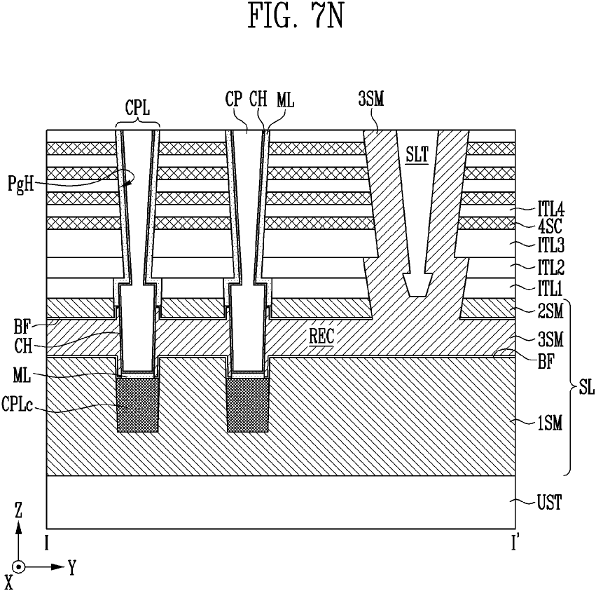

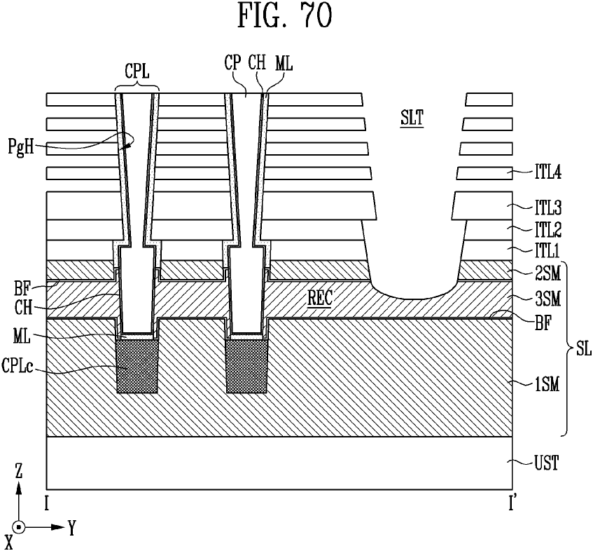

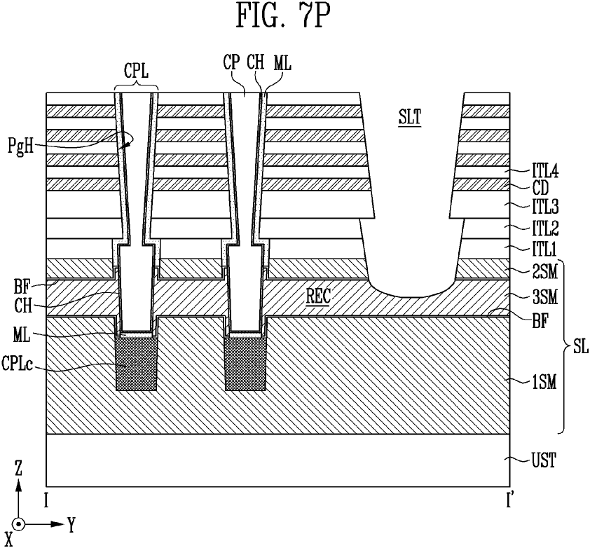

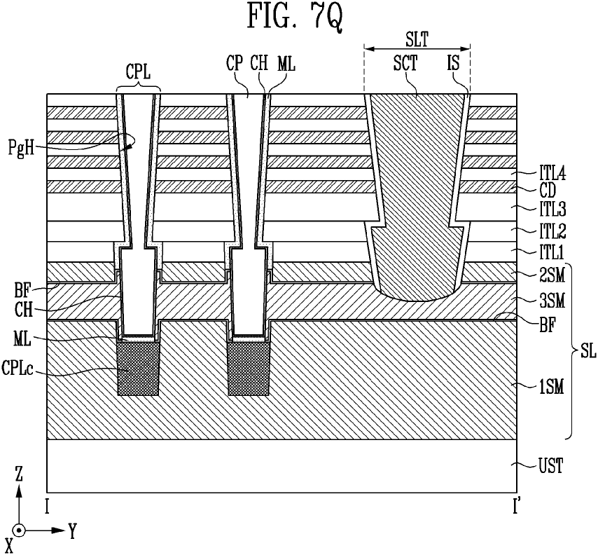

FIGS. 7A to 7Q are diagrams illustrating a method of manufacturing a memory device according to an embodiment of the present disclosure.

Referring to FIG. 7A, the first source layer 1SM, a first protective layer 1PT, a first sacrificial layer 1SC, a second protective layer 2PT, the second source layer 2SM, and a first interlayer insulating layer ITL1 may be stacked on a lower structure UST. The lower structure UST may be a substrate or a peripheral circuit structure. The peripheral circuit structure may include transistors and lines that are configured to perform the program, read, or erase operation. The first source layer 1SM may be a conductive layer that may be used as the source line and may be formed of polysilicon including an impurity. The first protective layer 1PT may be formed on the first source layer 1SM and may be used as a layer for protecting the surface of the first source layer 1SM during a subsequent etching process. The first protective layer 1PT may be formed of a material having an etch selectivity that is different from that of the first source layer 1SM. For example, the first protective layer 1PT may be formed of an oxide layer or a silicon oxide layer. The first sacrificial layer 1SC may be a material that is removed during a subsequent process and may be formed on the first protective layer 1PT. The first sacrificial layer 1SC may be formed of a material having an etch selectivity that is different from that of the first protective layer 1PT. For example, the first sacrificial layer 1SC may be formed of the same material as the first source layer 1SM. The second protective layer 2PT may be a layer for protecting the second source layer 2SM during a process of removing the first sacrificial layer 1SC and may be formed on the first sacrificial layer 1SC. For example, the second protective layer 2PT may be formed of a material having an etch selectivity that is different from that of the second source layer 2SM. For example, the second protective layer 2PT may be formed of the same material as the first protective layer 1PT. The second source layer 2SM may be a conductive layer that may be used as the source line and may be formed of polysilicon including an impurity. The first interlayer insulating layer ITL1 may be formed of an oxide layer or a silicon oxide layer. For example, the first source layer 1SM, the first sacrificial layer 1SC, and the second source layer 2SM may be formed of a material having an impurity concentration that is lower than a reference concentration that may minimize or prevent the occurrence of a physical defect of the first and second source layers 1SM and 2SM that are exposed during an etching process.

After the first source layer 1SM, the first protective layer 1PT, the first sacrificial layer 1SC, the second protective layer 2PT, the second source layer 2SM, and the first interlayer insulating layer ITL1 are stacked on the lower structure UST, the landing hole LdH that passes through the first interlayer insulating layer ITL1, the second source layer 2SM, the second protective layer 2PT, the first sacrificial layer 1SC, the first protective layer 1PT, and the first source 1SM may be formed. For example, the landing hole LdH may pass through the first interlayer insulating layer ITL1, the second source layer 2SM, the second protective layer 2PT, the first sacrificial layer 1SC, and the first protective layer 1PT in a vertical direction and may be formed so that the lowermost end is positioned in the first source layer 1SM. That is, an etching process for forming the landing hole LdH may be stopped before the lower structure UST is exposed.

Referring to FIG. 7B, the compensation plug CPLc may be formed in the landing hole LdH. The compensation plug CPLc may be formed of a conductive material. For example, the conductive material for the compensation plug CPLc may include an impurity having a concentration that is higher than that of the first or second source layer 1SM or 2SM. For example, the compensation plug CPLc may be formed of polysilicon. The impurity DP that is included in the compensation plug CPLc may be phosphorous or boron ion. In addition, various ions capable of improving the electrical characteristic of the source line may be used.

Referring to FIG. 7C, a portion of the compensation plug CPLc may be etched to lower a height of the compensation plug CPLc. The etching process for lowering the height of the compensation plug CPLc may be performed until the uppermost end of the compensation plug CPLc is lower than the uppermost end of the first source layer 1SM. For example, it is assumed that a height from the lowermost end to the uppermost end of the first source layer 1SM is a first height H1, a height from the lowermost end of the first source layer 1SM to the lowermost end of the landing hole LdH is a second height H2 is used, and a height from the lowermost end of the first source layer 1SM to the uppermost end of the compensation plug CPLc is a third height H3. In this case, the third height H3 may be set to be lower than the first height H1 but higher than the second height H2.

Referring to FIG. 7D, a second sacrificial layer 2SC may be formed on the compensation plug CPLc in the landing hole LdH. The second sacrificial layer 2SC may be formed of at least one of titanium nitride (TiN), tungsten (W), and carbon (C). When the second sacrificial layer 2SC is formed of the mixture of titanium nitride (TiN), tungsten (W), and carbon (C), a plurality of layers that are formed of different materials may be alternately stacked. For example, when the second sacrificial layer 2SC is formed of titanium nitride (TiN) and tungsten (W), a plurality of stack layers including titanium nitride (TiN) and tungsten (W) may be formed as the second sacrificial layer 2SC on the compensation plug CPLc. Subsequently, a second interlayer insulating layer ITL2 may be formed on the entire structure in which the second sacrificial layer 2SC is formed. Subsequently, a first trench 1TC may be formed by etching a portion of the second and first interlayer insulating layers ITL2 and ITL1, the second source layer 2SM, and the second protective layer 2PT, and a third sacrificial layer 3SC may be formed in the first trench 1TC. For example, the first trench 1TC may be formed in an area that is identical to an area in which the slit is to be formed, and an etching process for forming the first trench 1TC may be performed until the first sacrificial layer 1SC is exposed. The third sacrificial layer 3SC may be formed of at least one of titanium nitride (TiN), tungsten (W), and carbon (C). When the third sacrificial layer 3SC is formed of the mixture of titanium nitride (TiN), tungsten (W), and carbon (C), a plurality of layers that are formed of different materials may be alternately stacked. For example, when the third sacrificial layer 3SC is formed of titanium nitride (TiN) and tungsten (W), a plurality of stack layers including titanium nitride (TiN) and tungsten (W) may be formed as the third sacrificial layer 3SC on the compensation plug CPLc. After the third sacrificial layer 3SC is formed in the first trench 1TC, a third interlayer insulating layer ITL3 may be formed on the entire structure. The third interlayer insulating layer ITL3 may be formed of an oxide layer or a silicon oxide layer.

Referring to FIG. 7E, fourth sacrificial layers 4SC and fourth interlayer insulating layers ITL4 may be alternately stacked on the third interlayer insulating layer ITL3. The fourth sacrificial layers 4SC may be formed of a material having an etch selectivity that is different from that of the fourth interlayer insulating layers ITL4. For example, the fourth sacrificial layers 4SC may be formed of a nitride layer. The fourth interlayer insulating layers ITL4 may be formed of an oxide layer or a silicon oxide layer.

Referring to FIG. 7F, an etching process may be performed to form the plug hole PgH on the landing hole LdH. For example, the plug hole PgH may be formed by etching a portion of the fourth sacrificial layers 4SC and the fourth interlayer insulating layers ITL4 so that the second sacrificial layers 2SC of FIG. 7E, filled in the landing hole LdH, are exposed, and an etching process for removing the second sacrificial layers 2SC that are exposed through the plug hole PgH may be performed. Therefore, the plug hole PgH and the landing hole LdH may be connected to each other, and the compensation plug CPLc may be exposed through the plug hole PgH and the landing hole LdH.

Referring to FIG. 7G, the cell plug CPL may be formed on the compensation plug CPLc. Each of the cell plugs CPL may include the memory layer ML, the channel layer CH, and the core pillar CP that are sequentially formed along the plug hole PgH, a surface of the landing hole LdH, and an upper surface of the compensation plug CPLc. The memory layer ML may be formed in a cylindrical shape along an upper surface of the compensation plug CPLc, a side surface of the landing hole LdH, and a side surface of the plug hole PgH; the channel layer CH may be formed in a cylindrical shape along an inner surface of the memory layer ML; and the core pillar CP may be formed in a cylindrical shape that fills an inner area of the channel layer CH.

Among the cell plugs CPL, the cell plug CPL that is formed on the same layer as the fourth sacrificial layer 4SC may become a memory cell 61. An X-Y plane structure of the memory cell 61 is described as follows. The memory cell 61 may include the core pillar CP that is formed in a cylindrical shape. The memory cell 61 may also include the channel layer CH that surrounds a periphery of the core pillar CP, the tunnel insulating layer TO that surrounds a periphery of the channel layer CH, the charge trap layer CT that surrounds a periphery of the tunnel insulating layer TO, and the blocking layer BX that surrounds a periphery of the charge trap layer CT. The tunnel insulating layer TO, the charge trap layer CT, and the blocking layer BX that surround the channel layer CH may be included in the memory layer ML. A lower surface of the blocking layer BX that is included in the cell plug CPL may contact the compensation plug CPLc.

Referring to FIG. 7H, a second trench 2TC may be formed by etching a portion of the fourth sacrificial layers 4SC and the fourth interlayer insulating layers ITL4 that are stacked on the third sacrificial layer 3SC of FIG. 7G. For example, an etching process for forming the second trench 2TC may be performed until the third sacrificial layer 3SC that is filled in the first trench 1TC is exposed. When the third sacrificial layer 3SC is exposed through the second trench 2TC, an etching process for removing the exposed third sacrificial layer 3SC may be performed. Since an area from which the third sacrificial layer 3SC is removed becomes the first trench 1TC, the first and second trenches 1TC and 2TC may be connected to each other. Since the second trench 2TC is formed in a shape for dividing the memory blocks, the first and second trenches 1TC and 2TC may become the slit SLT for dividing the memory blocks.

Referring to FIG. 7I, third to fifth protective layers 3PT to 5PT may be sequentially formed along an inner surface of the slit SLT. The third to fifth protective layers 3PT to 5PT may be used as layers for protecting the fourth sacrificial layers 4SC or the fourth interlayer insulating layers ITL4 through the slit SLT in a subsequent etching process and may be formed in an order of a nitride layer, an oxide layer, and a nitride layer. For example, the third and fifth protective layers 3PT and 5PT may be formed of the nitride layer, and the fourth protective layer 4PT may be formed of the oxide layer.

Referring to FIG. 7J, an etching process may be performed to expose the first sacrificial layer 1SC through a lower portion of the slit SLT. For example, the etching process may be an anisotropic dry etching process so that the third to fifth protective layers 3PT to 5PT that are formed on a side surface of the slit SLT remain and the first sacrificial layer 1SC is exposed.

Referring to FIG. 7K, an etching process for removing the first sacrificial layer 1SC of FIG. 7J that is exposed through the lower portion of the slit SLT may be performed. For example, the etching process may be an isotropic dry etching process or a wet etching process. An empty area from which the first sacrificial layer 1SC is removed is defined as a recess REC. After the first sacrificial layer 1SC is removed, when the first and second protective layers 1PT and 2PT of FIG. 7J remain in the recess REC, an etching process or a cleaning process for removing the first and second protective layers 1PT and 2PT may be additionally performed. Accordingly, the memory layer ML, the first source layer 1SM, and the second source layer 2SM may be exposed through the recess REC.

Referring to FIG. 7L, etching processes for removing a portion of the memory layer ML that is exposed through the slit SLT and the recess REC may be performed. Specifically, a portion of the memory layer ML that is included in the cell plug CPL and exposed through the recess REC may be removed. Since the memory layer ML includes the blocking layer BX of FIG. 7G, the charge trap layer CT of FIG. 7G, and the tunnel insulating layer TO of FIG. 7G, etching processes for sequentially removing the blocking layer BX, the charge trap layer CT, and the tunnel insulating layer TC that are exposed through the recess REC may be sequentially performed. At this time, the third to fifth protective layers 3PT to 5PT that remain on the side surface of the slit SLT may also be sequentially removed. Accordingly, the channel layer CH that is included in the cell plug CPL may be exposed through the recess REC. When a portion of the memory layer ML that is exposed through the recess REC is removed, a portion of the memory layer ML that is formed in an area that overlaps the first and second source layers 1SM and 2SM may also be removed.

Referring to FIG. 7M, the buffer layer BF may be formed along the surface of the first and second source layers 1SM and 2SM that are exposed through the recess REC. The buffer layer BF may be used to reduce the growth speed of the third source layer 3SM during a formation process of the third source layer 3SM of FIG. 7N. The buffer layer BF may be formed of an insulating material. For example, the buffer layer BF may be formed of at least one of an oxide layer, a nitride layer, SiON, and SiCN. The buffer layer BF may be formed through a chemical vapor deposition method, a wet oxidation method, or a natural oxidation method or may be formed as an amorphous layer. When the buffer layer BF is formed through the chemical vapor deposition method, the buffer layer BF may be formed as a layer that is deposited along the surface of the first and second source layers 1SM and 2SM. When the buffer layer BF is formed through the wet oxidation method or the natural oxidation method, the buffer layer BF may be formed as a layer in which the surface of the first and second source layers 1SM and 2SM is partially oxidized. A gas or liquid for forming the buffer layer BF may be supplied through the slit SLT.

The buffer layer BF may be formed to have a thin thickness so that a current may flow between the first and second source layers 1SM and 2SM and the third source layer 3SM of FIG. 7N. For example, the minimum thickness of the buffer layer BF may be the thickness of one atomic layer, and the maximum thickness may be the thickness of the memory layer ML. The thickness of the buffer layer BF may be adjusted according to a type of the first to third source layers 1SM to 3SM and an electrical characteristic of the source line SL. Since the buffer layer BF is formed by the gas or liquid that is supplied through the slit SLT and the recess REC, the buffer layer BF may be formed on the surface of the first and second source layers 1SM and 2SM and a partial surface of the memory layer ML, the channel layer CH, and the compensation plug CPLc that are exposed through the recess REC. Even though the buffer layer BF is formed along a partial side surface of the channel layer CH, voltage that is applied to the third source layer 3SM may be transmitted to the channel layer CH because the thickness of the buffer layer BF is thin.

Referring to FIG. 7N, the third source layer 3SM may be formed in the recess REC through the slit SLT, and thus, the source line SL that is formed of the first to third source layers 1SM to 3SM and the buffer layer BF may be formed. For example, since the recess REC is connected to the slit SLT, when the recess REC is filled with the third source layer 3SM, the third source layer 3SM may be formed along a side surface of the slit SLT. The third source layer 3SM may be formed of a conductive material. For example, the third source layer 3SM may be formed of the same material as the first or second source layer 1SM or 2SM or may be formed of a material having an impurity of which a content is higher than that of the first or second source layer 1SM or 2SM. For example, the third source layer 3SM may be formed of a conductive material, such as polysilicon. The third source layer 3SM may be grown from the buffer layer BF that is formed along the surface of the first and second source layers 1SM and 2SM. Since the third source layer 3SM is formed along the surface of the buffer layer BF, rather than the first and second source layers 1SM and 2SM, grains configuring the first and second source layers 1SM and 2SM might not be used as the seed for forming the third source layer 3SM. Therefore, the third source layer 3SM may be grown more slowly than a case in which the third source layer 3SM is grown from the first and second source layers 1SM and 2SM. In other words, when a source gas for forming the third source layer 3SM is supplied into the recess REC in which the buffer layer BF is formed, the third source layer 3SM may be formed while the source ions that are included in the source gas are combined to the buffer layer BF. At this time, since the source ions that are included in the source gas do not directly contact the first and second source layers 1SM and 2SM and directly contact the buffer layer BF, the growth speed of the third source layer 3SM may be reduced. When the growth speed of the third source layer 3SM is reduced, the third source layer 3SM may be formed to have a uniform thickness along the entire surface including the corner of the first and second source layers 1SM and 2SM. Therefore, a phenomenon in which a seam or a void occurs between the first and second source layers 1SM and 2SM may be suppressed.

Referring to FIG. 7O, an etching process for removing a portion of the third source layer 3SM that is formed in the slit SLT may be performed. For example, since the third source layer 3SM is formed on a side surface and a lower surface of the slit SLT, the etching process for removing a portion of the third source layer 3SM that is formed in the slit SLT may be performed through an isotropic dry etching process or a wet etching process. The etching process may be performed until the third source layer 3SM that is formed on the side surface of the slit SLT is removed, and thus, a portion of the third source layer 3SM may remain under the slit SLT. Although the third source layer 3SM is exposed through the lower portion of the slit SLT in FIG. 7O, an etching process may be performed until the first source layer 1SM is exposed.

When the third source layer 3SM that is formed on the side surface of the slit SLT is removed, the fourth sacrificial layers 4SC of FIG. 7N may be exposed through the side surface of the slit SLT. Subsequently, an etching process for removing the fourth sacrificial layers 4SC that is exposed through the slit SLT may be performed. The etching process may be performed by using a source gas or an etchant having an etch selectivity for the fourth sacrificial layers 4SC, the etch selectivity being higher than that of the fourth interlayer insulating layer ITL4 so that the fourth interlayer insulating layers ITL4 remain.

Referring to FIG. 7P, the conductive layers CD may be filled between the fourth interlayer insulating layers ITL4. The conductive layers CD may be used as a word line or a select line of the memory block, and thus, the conductive layers CD may be formed of a conductive material. For example, the conductive layers CD may be formed of a metal material, such as tungsten (W), molybdenum (Mo), cobalt (Co), nickel (Ni), or a semiconductor material such as silicon (Si) or polysilicon (Poly-Si), but is not limited thereto.

Referring to FIG. 7Q, the insulating layer IS may be formed along the side surface of the slit SLT, and the source contact SCT may be formed inside the slit SLT in which the insulating layer IS is formed. Since the insulating layer IS is formed along the side surface of the slit SLT, the third source layer 3SM that remains under the slit SLT may be exposed through the slit SLT. Subsequently, when a conductive material for the source contact SCT is filled in the slit SLT, the third source layer 3SM that is exposed through the lower portion of the slit SLT may contact the source contact SCT. When the first source layer 1SM is exposed through a lower surface of the slit SLT, the source contact SCT may contact the first and third source layers 1SM and 3SM.

Accordingly, when a source voltage is applied to the source contact SCT, the source voltage may be transmitted to the channel layer CH through the source line SL. Since the compensation plug CPLc may reduce a resistance between the source line SL and the cell plug CPL, an electrical characteristic of the memory device using the source line SL may be improved.

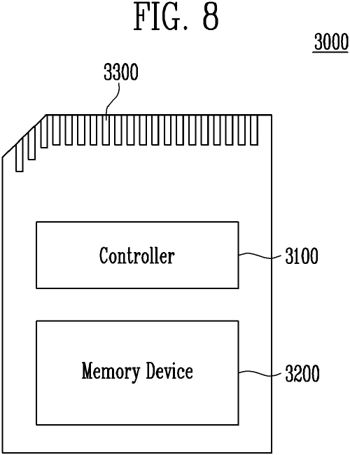

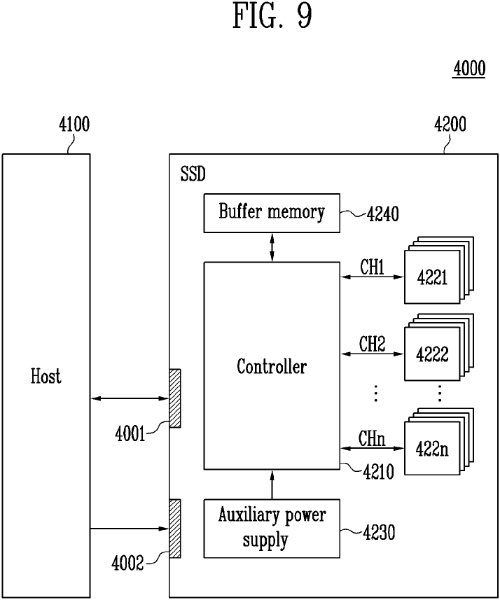

FIG. 8 is a diagram illustrating a memory card system to which a memory device of the present disclosure is applied.

Referring to FIG. 8, the memory card system 3000 may include a controller 3100, a memory device 3200, and a connector 3300.

The controller 3100 may be connected to the memory device 3200. The controller 3100 may be configured to access the memory device 3200. For example, the controller 3100 may be configured to control a program, read, or erase operation of the memory device 3200 or to control a background operation. The controller 3100 may be configured to provide an interface between the memory device 3200 and a host. The controller 3100 may be configured to drive firmware for controlling the memory device 3200. For example, the controller 3100 may include components, such as a random access memory (RAM), a processing unit, a host interface, a memory interface, and an error correction circuit.

The controller 3100 may communicate with an external device through the connector 3300. The controller 3100 may communicate with an external device (for example, the host) according to a specific communication standard. For example, the controller 3100 may be configured to communicate with an external device through at least one of various communication standards, such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe. For example, the connector 3300 may be defined by at least one of the various communication standards described above.

The memory device 3200 may include a plurality of memory cells and may be configured identically to the memory device 1100 shown in FIG. 1.

The controller 3100 and the memory device 3200 may be integrated into one semiconductor device to configure a memory card. For example, the controller 3100 and the memory device 3200 may be integrated into one semiconductor device to configure a memory card, such as a PC memory card (personal computer memory card (PCMCIA)), a compact flash card (CF), a smart media card (SM or SMC), a memory stick, a multimedia card (MMC, RS-MMC, MMCmicro, or eMMC), an SD card (SD, miniSD, microSD, or SDHC), and a universal flash storage (UFS).

FIG. 9 is a diagram illustrating a solid state drive (SSD) system to which a memory device of the present disclosure is applied.

Referring to FIG. 9, the SSD system 4000 may include a host 4100 and an SSD 4200. The SSD 4200 may exchange a signal with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to the signal received from the host 4100. For example, the signal may be signals based on an interface between the host 4100 and the SSD 4200. For example, the signal may be a signal that is defined by at least one of interfaces such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe.

The plurality of memory devices 4221 to 422n may include a plurality of memory cells that are configured to store data. Each of the plurality of memory devices 4221 to 422n may be configured identically to the memory device 1100, shown in FIG. 1. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive a power voltage from the host 4100 and may charge the power voltage. The auxiliary power supply 4230 may provide a power voltage of the SSD 4200 when power supply from the host 4100 is not smooth. For example, the auxiliary power supply 4230 may be positioned inside of the SSD 4200 or may be positioned outside of the SSD 4200. For example, the auxiliary power supply 4230 may be positioned on a main board and may provide auxiliary power to the SSD 4200.

The buffer memory 4240 may operate as a buffer memory of the SSD 4200. For example, the buffer memory 4240 may temporarily store data that is received from the host 4100 or data that is received from the plurality of memory devices 4221 to 422n or may temporarily store data (for example, a mapping table) of the memory devices 4221 to 422n. The buffer memory 4240 may include a volatile memory, such as a DRAM, an SDRAM, a DDR SDRAM, and an LPDDR SDRAM, or a nonvolatile memory such as an FRAM, a ReRAM, an STT-MRAM, and a PRAM.

What is claimed is:

1. A memory device comprising:
a source line including a plurality of source layers and a buffer layer, the buffer layer being formed between the plurality of source layers;
a stack structure formed on the source line;
a cell plug contacting the source line by passing through the stack structure;
a slit separating the stack structure; and
a source contact formed in the slit and contacting the source line.

2. The memory device of claim 1, wherein the plurality of source layers are formed of a conductive material, and
wherein the buffer layer is formed of an insulating material.

3. The memory device of claim 1, wherein the plurality of source layers are formed of at least one material that is selected from polysilicon, tungsten, and nickel, or a combination of selected materials.

4. The memory device of claim 1, wherein the buffer layer is formed of at least one an oxide layer, a nitride layer, SiON, and SiCN.

5. The memory device of claim 1, wherein the cell plug is formed in a plug hole that passes through the stack structure and a landing hole that passes through a portion of the source line.

6. The memory device of claim 5, wherein the cell plug comprises:
a core pillar formed in the plug hole and the landing hole;
a channel layer surrounding the core pillar; and
memory layers surrounding the channel layer.

7. The memory device of claim 6, wherein portions of each of the memory layers are removed in an area in which the source line and the cell plug overlap.

8. The memory device of claim 6, wherein the core pillar and the channel layer extend from an uppermost end to a lowermost end of the cell plug.

9. The memory device of claim 1, wherein the source line is formed of polysilicon including an impurity.

10. The memory device of claim 1, wherein the stack structure includes conductive layers and interlayer insulating layers that are alternately stacked.

11. The memory device of claim 1, further comprising:
a compensation plug formed below the cell plug in the source line.

12. The memory device of claim 11, wherein the compensation plug is formed of a material having an impurity concentration that is higher than that of the source line.

13. The memory device of claim 12, wherein the impurity is a phosphorous or boron ion.

14. The memory device of claim 1, wherein the number of the buffer layers is changed according to the number of the plurality of source layers.

15. The memory device of claim 14, wherein, when the number of the plurality of source layers is N, the number of the buffer layers is N-1, and
wherein N is a natural number greater than or equal to 2.

16. A method of manufacturing a semiconductor memory device, the method comprising:
stacking a first sacrificial layer and a second source layer on a first source layer;
forming a landing hole that exposes a portion of the first source layer by etching the second source layer, the first sacrificial layer, and a portion of the first source layer;
forming a cell plug inside the landing hole;
forming a slit that exposes a portion of the first sacrificial layer by etching the second source layer and a portion of the first sacrificial layer;
forming a recess between the first and second source layers by removing the first sacrificial layer that is exposed through the slit;
forming a buffer layer along a surface of the first and second source layers exposed through the recess;
forming a third source layer in the recess in which the buffer is formed to form a source line including the first to third source layers and the buffer layer; and
forming a source contact in the slit.

17. The method of claim 16, wherein the first to third source layers are formed of a conductive material.

18. The method of claim 16, wherein forming the cell plug comprises:
forming a blocking layer along a side surface of the landing hole;
forming a charge trap layer along an inner surface of the blocking layer;
forming a tunnel insulating layer along an inner surface of the charge trap layer;
forming a channel layer along an inner surface of the tunnel insulating layer; and
forming a core pillar in an area that is surrounded by the channel layer.

19. The method of claim 16, wherein the buffer layer is formed of an insulating material.

20. The method of claim 16, wherein the buffer layer is formed of at least one of an oxide layer, a nitride layer, SiON, and SiCN.

21. The method of claim 16, wherein the buffer layer is formed of an amorphous layer.

22. The method of claim 16, wherein forming the buffer layer is performed through a chemical vapor deposition method, a wet oxidation method, or a natural oxidation method.
